(19) United States
(12) Patent Application Publication
(10) Pub. No.: US 2014/0365172 A1
(43) Pub. Date: Dec. 11, 2014

(54) METHOD FOR ESTIMATING DISTRIBUTION CURVE OF STORING STATE OF SOLID STATE STORAGE DEVICE

(71) Applicant: Lite-On IT Corporation, Taipei (TW)

(72) Inventors: Yen-Chin Liao, Hsinchu (TW); Hsie-Chia Chang, Hsinchu (TW); Shih-Jia Zeng, Hsinchu (TW)

(73) Assignee: Lite-On IT Corporation, Taipei (TW)

(21) Appl. No.: 14/034,687

(22) Filed: Sep. 24, 2013

(30) Foreign Application Priority Data
Jun. 8, 2013 (CN) 201310229698.X

(51) Int. Cl. G01R 31/26; G11C 16/06

(52) U.S. Cl. CPC G01R 31/2642; G11C 16/06
USPC 702/179

(57) ABSTRACT

A method for estimating a distribution curve of a first storing state of a solid state storage device includes the following steps. Firstly, plural threshold voltage intervals are provided. Numbers of cells within respective threshold voltage intervals are calculated. A location parameter interval is determined according to the numbers of cells within the threshold voltage intervals. The percentages of the cells within respective threshold voltage intervals are determined, and thus a distribution curve table is established. Then, m candidate location parameters within the location parameter interval are determined, and n candidate scale parameters are set. According to the m candidate location parameters and the n candidate scale parameters, m×n candidate Gaussian distribution curves are determined. A first Gaussian distribution curve selected from the m×n candidate Gaussian distribution curves is defined as the distribution curve.

This application claims the benefit of People's Republic of China Application Serial No. 201310229698.X, filed Jun. 8, 2013, the subject matter of which is incorporated herein by reference.

### FIELD OF THE INVENTION

The present invention relates to a method for estimating a distribution curve of a storing state of a solid state storage device, and more particularly to a method for estimating a Gaussian distribution curve of a storing state of a solid state storage device.

### BACKGROUND OF THE INVENTION

As is well known, the solid state storage devices using NAND-based flash memories are widely used in a variety of electronic devices. For example, a SD card or a solid state drive (SSD) is a solid state storage device that uses a NAND-based flash memory to store data.

According to the data amount to be stored, the NAND-based flash memories may be classified into three types, i.e. a single-level cell (SLC) flash memory, a multi-level cell (MLC) flash memory and a triple-level cell (TLC) flash memory. The SLC flash memory can store only one bit of data per cell. The MLC flash memory can store two bits of data per cell. The TLC flash memory can store three bits of data per cell.

FIG. 1 schematically illustrates the architecture of cells of a solid state storage device. As shown in FIG. 1, the solid state storage device comprises plural cells. Each cell comprises a floating gate transistor. The cell is a SLC cell, a MLC cell or a TLC cell. Moreover, these cells of the solid state storage device are arranged in several columns. The cells arranged in the same column are connected with each other. Moreover, the cells arranged in the same row are controlled by a corresponding word line.

Generally, the floating gate transistor of each cell has a floating gate to store hot carriers. A threshold voltage (V_{TH}) of the floating gate transistor is determined according to the amount of the stored hot carriers. If a floating gate transistor has a higher threshold voltage, it means that a higher gate voltage is required to turn on the floating gate transistor. Whereas, if a floating gate transistor has a lower threshold voltage, it means that the floating gate transistor can be turned on by a lower gate voltage.

During a program cycle of the flash memory, the threshold voltage of the floating gate transistor may be changed by controlling the amount of hot carriers to be injected into the floating gate. During a read cycle, a sensing circuit of the solid state storage device may judge the storing state of the floating gate transistor according to the threshold voltage of the floating gate transistor.

FIG. 2 schematically illustrates the threshold voltage distribution curves of a MLC solid state storage device in different storing states. Generally, according to the amount of the injected hot carriers, each cell of the MLC solid state storage device has four storing states E, A, B and C. Before the hot carriers are injected into the cell, the cell is in a storing state E (e.g. the logic state is 11). As the number of hot carriers injected into the cell is gradually increased, the cell is sequentially switched to the storing state A (e.g. the logic state is 10), the storing state B (e.g. the logic state is 00) and the storing state C (e.g. the logic state is 01). Moreover, the voltage level in the storing state C>the voltage level in the storing state B>the voltage level in the storing state A>the voltage level in the storing state E. After an erase cycle, the cell is restored to the storing state E, and no hot carriers are retained in the floating gate transistor.

In practice, even if many cells are programmed to have the same storing state during the program cycle, the threshold voltages of these cells are not all identical. That is, the threshold voltages of these cells are distributed in a specified distribution curve with a median threshold voltage. For example, as shown in FIG. 2, the cells in the storing state E have a median threshold voltage V_{THE} (e.g. 0V), the cells in the storing state A have a median threshold voltage V_{THA} (e.g. 10V), the cells in the storing state B have a median threshold voltage V_{THB} (e.g. 20V), and the cells in the storing state C have a median threshold voltage V_{THC} (e.g. 30V). For example, according to statistics, the greatest number of cells in the storing state C has the median threshold voltage V_{THC} (e.g. 30V).

As shown in FIG. 2, after the distribution curves of various storing states of the MLC solid state storage device are determined, a first sensing voltage Vs1, a second sensing voltage Vs2 and a third sensing voltage Vs3 are generated. During the read cycle, the first sensing voltage Vs1, the second sensing voltage Vs2 and the third sensing voltage Vs3 may be employed to detect the storing states of the cells of the MLC solid state storage device.

In case that the threshold voltage of a cell is lower than the first sensing voltage Vs1, it is considered that the cell has a storing state E. If the threshold voltage of the cell is higher than the first sensing voltage Vs1 and lower than the second sensing voltage Vs2, the cell has a storing state A. If the threshold voltage of a cell is higher than the second sensing voltage Vs2 and lower than the third sensing voltage Vs3, it is considered that the cell has a storing state B. If the threshold voltage of a cell is higher than the third sensing voltage Vs3, it is considered that the cell has a storing state C.

Generally, the settings of the sensing voltages may influence the data error rate. For example, in the solid state storage device of FIG. 2, a total of p cells are programmed to have the storing state E. When the first sensing voltage Vs1 is employed to detect the p cells, the threshold voltages of the floating gates of only (p−q) cells are lower than the first sensing voltage Vs1. Consequently, only (p−q) cells are turned on, and the sensing circuit of the solid state storage device may confirm that the (p−q) cells have the storing state E. On the other hand, the threshold voltages of the floating gates of the other q cells are higher than the first sensing voltage Vs1. Under this circumstance, the q cells are unable to be turned on, and the sensing circuit of the solid state storage device fails to be considered to have the storing state E. Moreover, if a sensing voltage lower than the first sensing voltage Vs1 is employed to detect the p cells, less than (p−q) cells are considered to have the storing state E. Whereas, if a sensing voltage higher than the first sensing voltage Vs1 is employed to detect the p cells, more than (p−q) cells are considered to have the storing state E.

Of course, the above method may be applied to a SLC solid state storage device and a TLC solid state storage device. When the above method is applied to the SLC solid state storage device, one sensing voltage is sufficient to detect two storing states of the SLC solid state storage device. When the above method is applied to the TLC solid state storage device, seven sensing voltages are employed to detect eight storing states of the TLC solid state storage device. The operating principles are similar to those mentioned above, and are not redundantly described herein.

For acquiring the threshold voltage distribution curves as shown in FIG. 2, various known storing states are recorded into the cells of the solid state storage device during the program cycle, and then the threshold voltages of all cells are detected and statistic data about the threshold voltages and the storing states are gathered. Afterwards, the threshold voltage distribution curves as shown in FIG. 2 are obtained, and the sensing voltages are created. However, since it is necessary to successively detect the threshold voltages of all cells and gather the statistic data, the conventional method of acquiring the threshold voltage distribution curves is very troublesome and time-consuming, and this method is limited to be implemented before the solid state storage device leaves the factory.

After the solid state storage device leaves the factory, if the solid state storage device has been written and erased many times, the threshold voltage distribution curve of each storing state of the solid state storage device are possibly changed. Under this circumstance, the median threshold voltage is shifted. If the above method is utilized to acquire the threshold voltage distribution curves of different storing states by gathering the statistic data, new sensing voltages can be created to reduce the data error rate. However, since the solid state storage device is under control of the user after the solid state storage device leaves the factory, it is impossible to utilize the above method to gather the statistic data and acquire the threshold voltage distribution curves of different storing states. In other words, after the solid state storage device has been used for a long term, if the old sensing voltages obtained at the factory are still used to distinguish the storing states of the cells from each other, the data error rate of the solid state storage device will be increased.

### SUMMARY OF THE INVENTION

An embodiment of the present invention provides a method for estimating a distribution curve of a storing state of a solid state storage device. The solid state storage device has M cells with a first storing state. The distribution curve estimation method includes the following steps. Firstly, plural threshold voltages are provided to define plural threshold voltage intervals. Then, numbers of cells within respective threshold voltage intervals are calculated. A location parameter interval is determined according to the numbers of cells within the threshold voltage intervals. Then, the percentages of the cells within respective threshold voltage intervals are determined, and thus a distribution curve table is established. Then, m candidate location parameters within the location parameter interval are determined, and n candidate scale parameters are set. Then, m×n candidate Gaussian distribution curves are determined according to the m candidate location parameters and the n candidate scale parameters. A first Gaussian distribution curve is selected from the m×n candidate Gaussian distribution curves, and the first Gaussian distribution curve is defined as the distribution curve of the first storing state.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) schematically illustrates the architecture of cells of a solid state storage device;

FIG. 2 (prior art) schematically illustrates the threshold voltage distribution curves of a MLC solid state storage device in different storing states;

FIG. 3A schematically illustrates some Gaussian distribution curves with different parameters;

FIG. 3B schematically illustrates the applications of the Gaussian distribution curve;

FIG. 4 is a flowchart illustrating a process of determining a location parameter interval according to an embodiment of the present invention;

FIGS. 5A˜5E schematically illustrate an example of determining a location parameter interval according to an embodiment of the present invention;

FIG. 6 is a table illustrating the relationships between plural candidate location parameters and plural candidate scale parameters for defining plural candidate Gaussian distribution curves;

FIGS. 7A˜7E schematically illustrate the percentages of the cell number of four candidate Gaussian distribution curves GD21˜GD24 within various threshold voltage intervals;

FIG. 8 is a table illustrating the percentages corresponding to the candidate Gaussian distribution curves GD11˜GD64 and various threshold voltage intervals; and

FIG. 9 is a flowchart illustrating a method for estimating a distribution curve of a storing state of a solid state storage device according to an embodiment of the present invention.

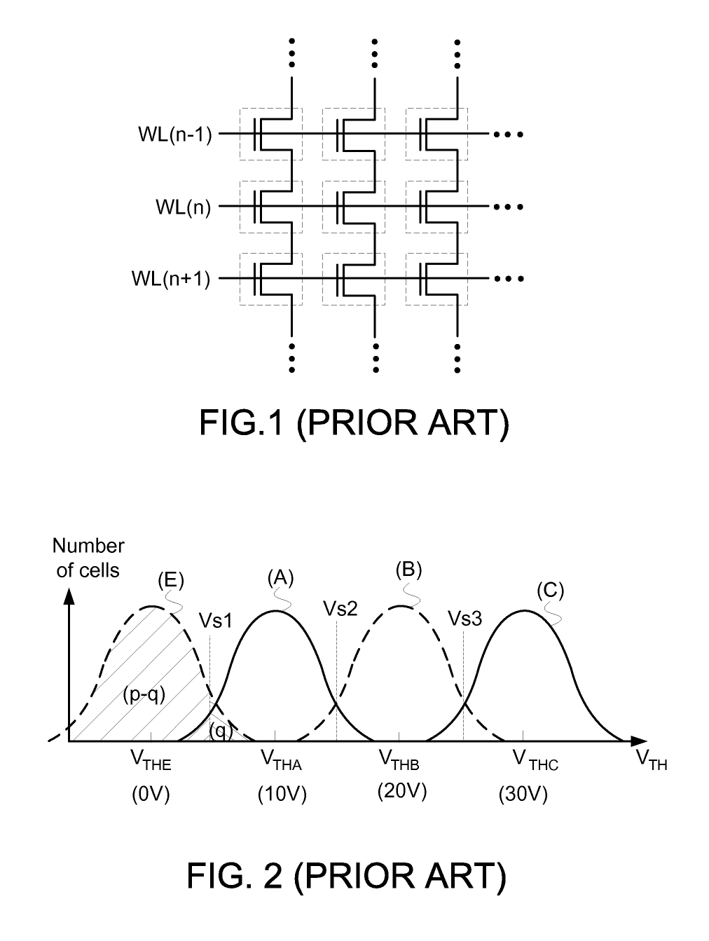

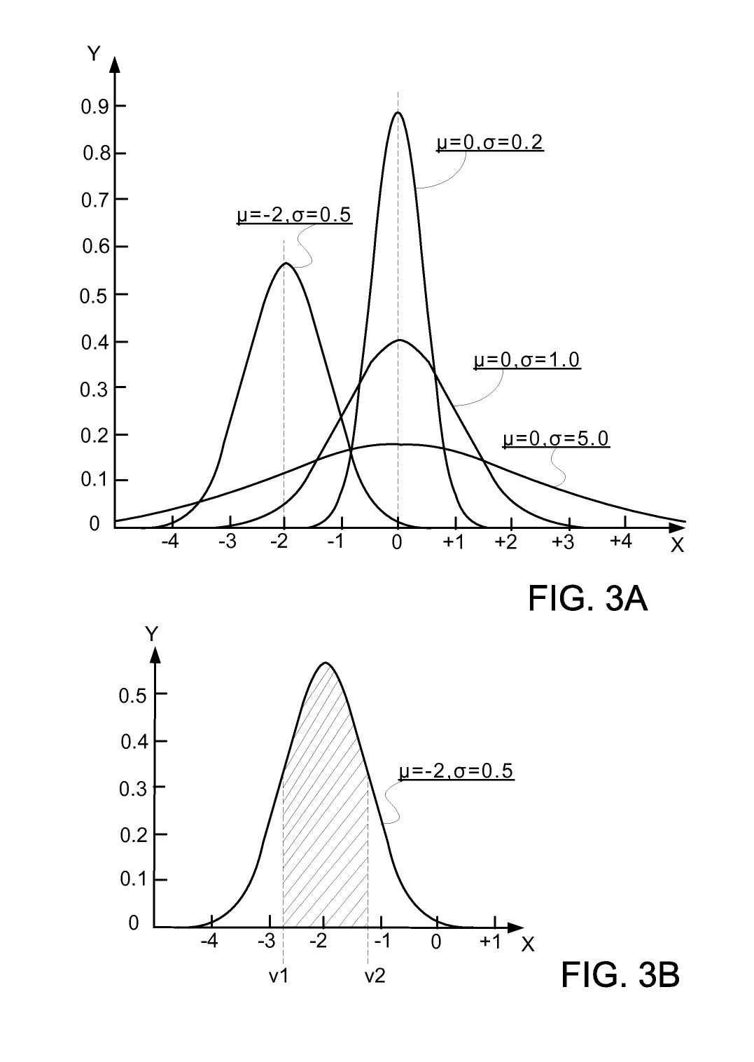

### DETAILED DESCRIPTION OF PREFERRED EMBODIMENTS

As previously described, the conventional method of acquiring a threshold voltage distribution curve of a solid state storage device is very troublesome and time-consuming. For solving the drawbacks, the present invention provides a method for estimating a distribution curve of a storing state of a solid state storage device. The method of the present invention is capable of quickly estimating the distribution curve of a storing state of a solid state storage device after the solid state storage device leaves the factory. Of course, the method of the present invention also can be utilized to estimate the distribution curve of a storing state of a solid state storage device before the solid state storage device leaves the factory.

Generally, the distribution curve of the storing state of the solid state storage device has the Gaussian-like characteristics. In accordance with the present invention, a Gaussian distribution curve with specified parameters is determined as the distribution curve of the storing state by calculation.

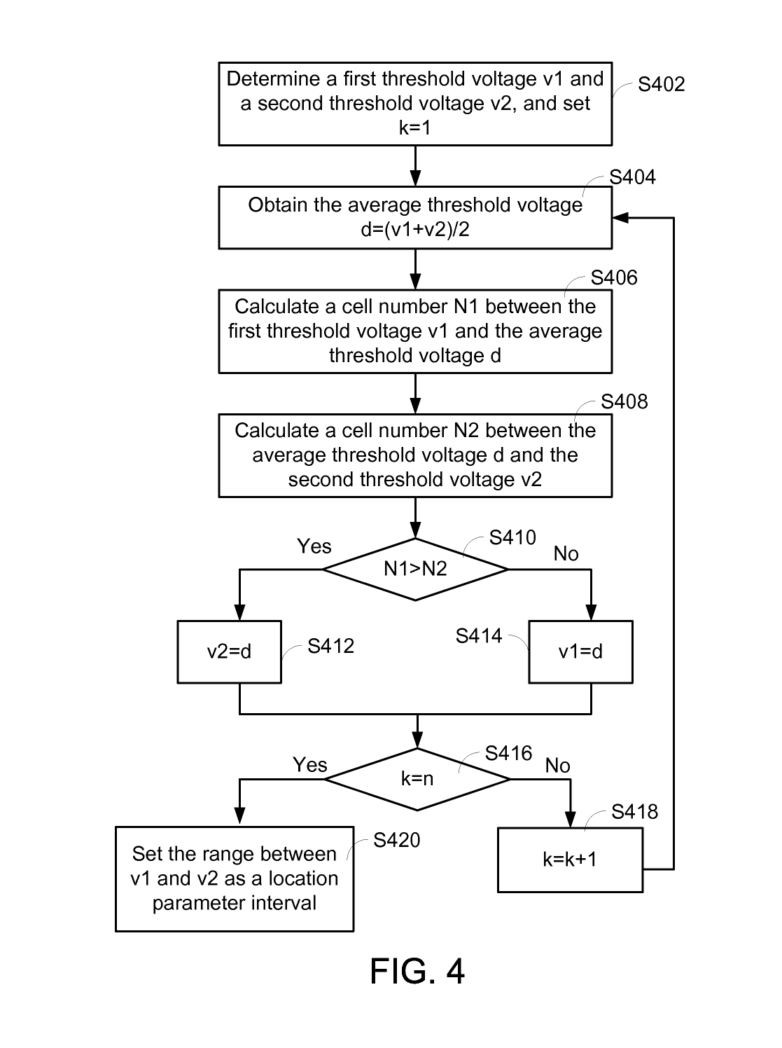

As is well known, the parameters of the Gaussian distribution curve include a location parameter μ (mean) and a scale parameter σ (sigma). FIG. 3A schematically illustrates some Gaussian distribution curves with different parameters. FIG. 3B schematically illustrates the applications of the Gaussian distribution curve. The location parameter μ indicates the X-axis location corresponding to a peak value of the Gaussian distribution curve. The scale parameter σ indicates the wide or narrow extent of the Gaussian distribution curve. Please refer to FIG. 3A again. As the scale parameter σ decreases, the Gaussian distribution curve becomes taller and narrower. As the scale parameter σ increases, the Gaussian distribution curve becomes shorter and wider.

Please refer to FIG. 3B again. After the location parameter μ and the scale parameter σ are determined, the area N(v1,v2) under the Gaussian distribution curve and between any two locations (e.g. v1 and v2) of the X axis may be calculated by the following equations:

$$\begin{matrix}N ( v 1 , v 2 ) = \frac{1}{2} erf ( \frac{v 2 - μ}{\sqrt{2} σ} ) - \frac{1}{2} erf ( \frac{v 1 - μ}{\sqrt{2} σ} ) , \\ and & ( 1 ) \\ erf ( x ) = \frac{1}{2} + {\int }_{0}^{x} {e}^{- {t}^{2}} d t & ( 2 )\end{matrix}$$

From the above discussions, after the location parameter μ and the scale parameter σ are determined, a Gaussian distribution curve with a specified shape is defined. Moreover, if a threshold voltage distribution curve of a specified storing state complies with the Gaussian distribution curve, the area under the Gaussian distribution curve and between any two locations v1 and v2 of the X axis may be defined as the percentage of the cell number between any two threshold voltages v1 and v2.

The above operating principles may be applied to the method of the present invention. That is, by detecting the numbers of cells of the solid state storage device within plural threshold voltage intervals, a location parameter and a scale parameter are determined. According to the location parameter and the scale parameter, a corresponding Gaussian distribution curve is generated. The Gaussian distribution curve is used as the distribution curve of the storing state. The operating principles of the present invention will be illustrated in more details as follows.

After the solid state storage device has been written and erased many times, the threshold voltage distribution curve of each storing state of the solid state storage device are possibly changed. Under this circumstance, the median threshold voltage is shifted.

In accordance with the present invention, plural threshold voltages are provided by the solid state storage device to define plural threshold voltage intervals, and a location parameter interval is determined by gathering statistics about the numbers of cells within respective threshold voltage intervals. Hereinafter, an example of estimating the distribution curve of a specified storing state will be illustrated. Moreover, it is assumed that the solid state storage device has M cells with the specified storing state.

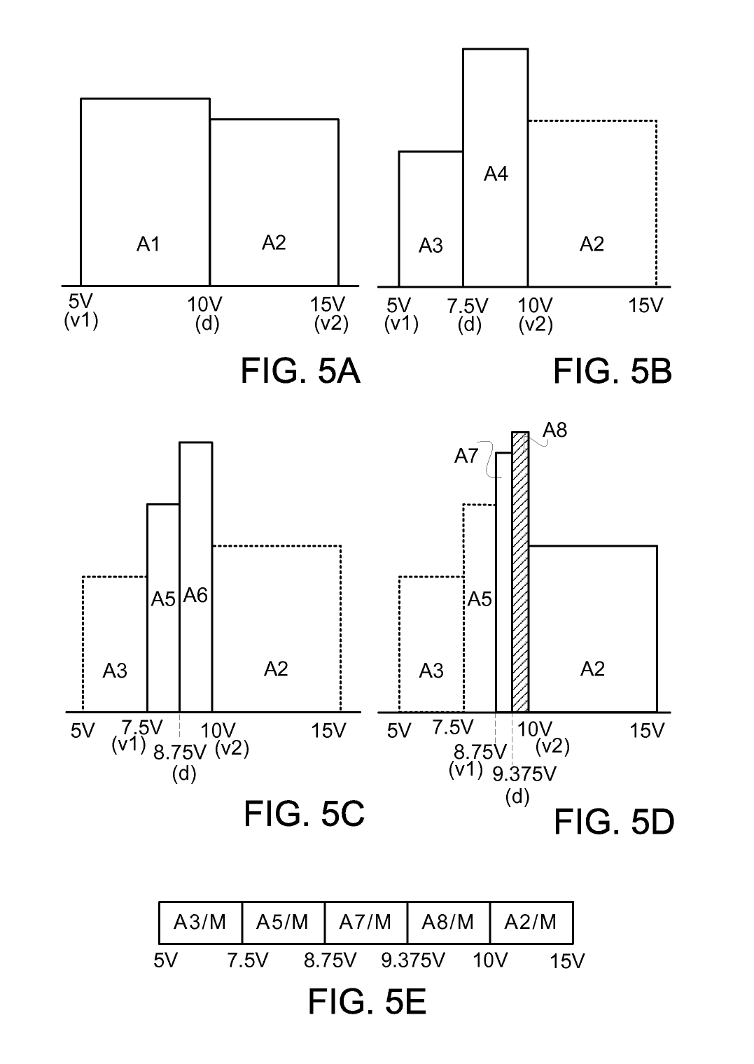

FIG. 4 is a flowchart illustrating a process of determining a location parameter interval according to an embodiment of the present invention.

Firstly, in the step S402, a first threshold voltage v1 and a second threshold voltage v2 are determined, and k is set as one (k=1). Then, in the step S404, an average threshold voltage d is obtained according to the first threshold voltage v1 and the second threshold voltage v2, i.e. d=(v1+v2)/2. Moreover, the cells having the first threshold voltage v1 and the second threshold voltage v2 are all considered to have the specified storing state.

Next, in the step S406, a cell number N1 between the first threshold voltage v1 and the average threshold voltage d is calculated. In particular, a first sensed cell number is acquired by using the first threshold voltage v1 as the sensing voltage, and a second sensed cell number is acquired by using the average threshold voltage d as the sensing voltage. After the first sensed cell number is subtracted from the second sensed cell number, the cell number N1 between the first threshold voltage v1 and the average threshold voltage d is obtained.

Next, in the step S408, a cell number N2 between the average threshold voltage d and the second threshold voltage v2 is calculated. In particular, a third sensed cell number is acquired by using the second threshold voltage v2 as the sensing voltage. After the second sensed cell number is subtracted from the third sensed cell number, the cell number N2 between the average threshold voltage d and the second threshold voltage v2 is obtained.

If an inequality N1>N2 is satisfied (Step S410), set v2=d (Step S412). Whereas, if the inequality N1>N2 is not satisfied (Step S410), set v1=d (Step S414).

Next, if an equation k=n is not satisfied (Step S416), set k=k+1 (Step S418) and go back to the step S404. Whereas, if the equation k=n is satisfied (Step S416), the range between v1 and v2 is set as the location parameter interval (Step S420). In the step S416, n is the number of loops for processing this flowchart. As n increases, the location parameter interval becomes narrower.

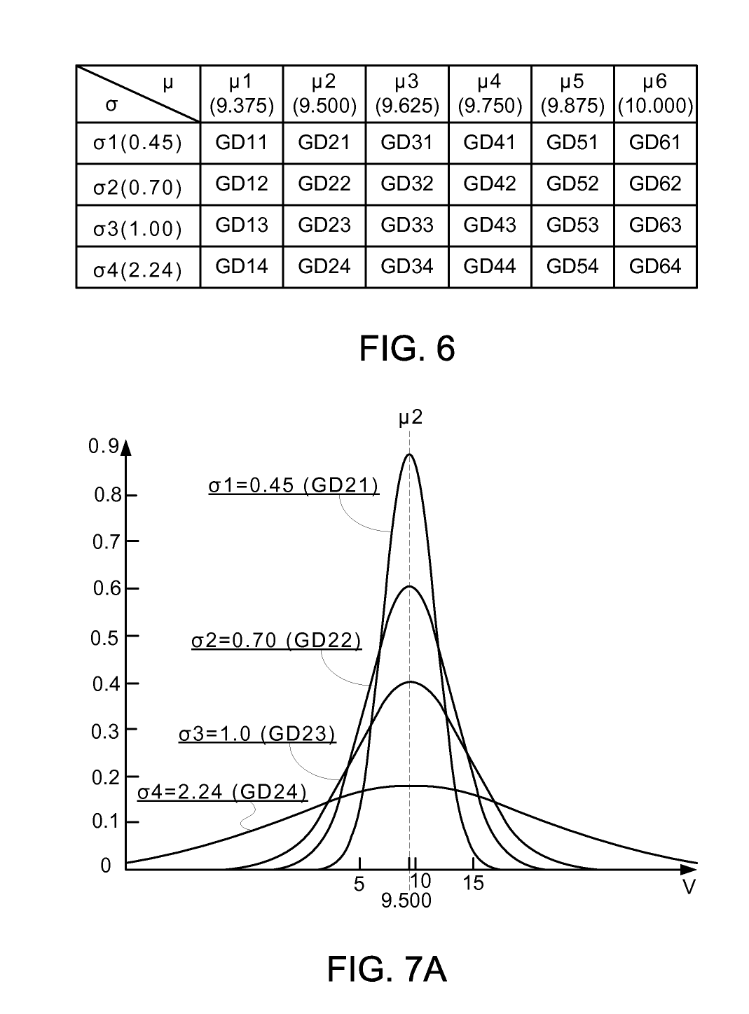

FIGS. 5A-5E schematically illustrate an example of determining a location parameter interval according to an embodiment of the present invention. In this embodiment, the specified storing state is the storing state A, k=1, n=4, v1=5V, and v2=15V. Moreover, v1 and v2 are included in the threshold voltage range of the storing state A.

As shown in FIG. 5A, the average threshold voltage d is equal to 10V. By calculation, the cell number N1 between the first threshold voltage v1 and the average threshold voltage d is A1 (i.e. N1=A1), and the cell number N2 between the average threshold voltage d and the second threshold voltage v2 is A2 (i.e. N2=A2). As shown in FIG. 5A, N1>N2. It means that the location parameter μ is between 5V and 10V. Meanwhile, set k=2 and v2=10V. The procedure of searching the location parameter interval is continuously performed.

As shown in FIG. 5B, v1=5V, v2=10V, and d=7.5V. By calculation, the cell number N1 between the first threshold voltage v1 and the average threshold voltage d is A3 (i.e. N1=A3), and the cell number N2 between the average threshold voltage d and the second threshold voltage v2 is A4 (i.e. N2=A4). As shown in FIG. 5B, N2>N1. It means that the location parameter μ is between 7.5V and 10V. Meanwhile, set k=3 and v1=7.5V. The procedure of searching the location parameter interval is continuously performed.

As shown in FIG. 5C, v1=7.5V, v2=10V, and d=8.75V. By calculation, the cell number N1 between the first threshold voltage v1 and the average threshold voltage d is A5 (i.e. N1=A5), and the cell number N2 between the average threshold voltage d and the second threshold voltage v2 is A6 (i.e. N2=A6). As shown in FIG. 5C, N2>N1. It means that the location parameter μ is between 8.75V and 10V. Meanwhile, set k=4 and v1=8.75V. The procedure of searching the location parameter interval is continuously performed.

As shown in FIG. 5D, v1=8.75V, v2=10V, and d=9.375V. By calculation, the cell number N1 between the first threshold voltage v1 and the average threshold voltage d is A7 (i.e. N1=A7), and the cell number N2 between the average threshold voltage d and the second threshold voltage v2 is A8 (i.e. N2=A8). As shown in FIG. 5D, N2>N1. It means that the location parameter μ is between 9.375V and 10V. Meanwhile, since k=n=4, the loop is ended. In addition, the range between v1 and v2 (i.e. 9.375V˜10V) is set as the location parameter interval.

After the location parameter interval is determined by the procedures of FIGS. 5A˜5D, a known distribution curve table as shown in FIG. 5E is established in the solid state storage device. The known distribution curve table indicates the relationships between the threshold voltage intervals and corresponding percentages. The percentage denotes a ratio of the cell number within each threshold voltage interval divided by the number of cells with the specified storing state (i.e. M cells). In this embodiment, the percentage within the threshold voltage interval between 5V and 7.5V is A3/M, the percentage within the threshold voltage interval between 7.5V and 8.75V is A5/M, the percentage within the threshold voltage interval between 8.75V and 9.375V is A7/M, the percentage within the threshold voltage interval between 9.375V and 10V is A8/M, and the percentage within the threshold voltage interval between 10V and 15V is A2/M. Moreover, since the peak value of the known distribution curve table lies within 9.375V and 10V, it is considered that the location parameter μ lies between 9.375V and 10V.

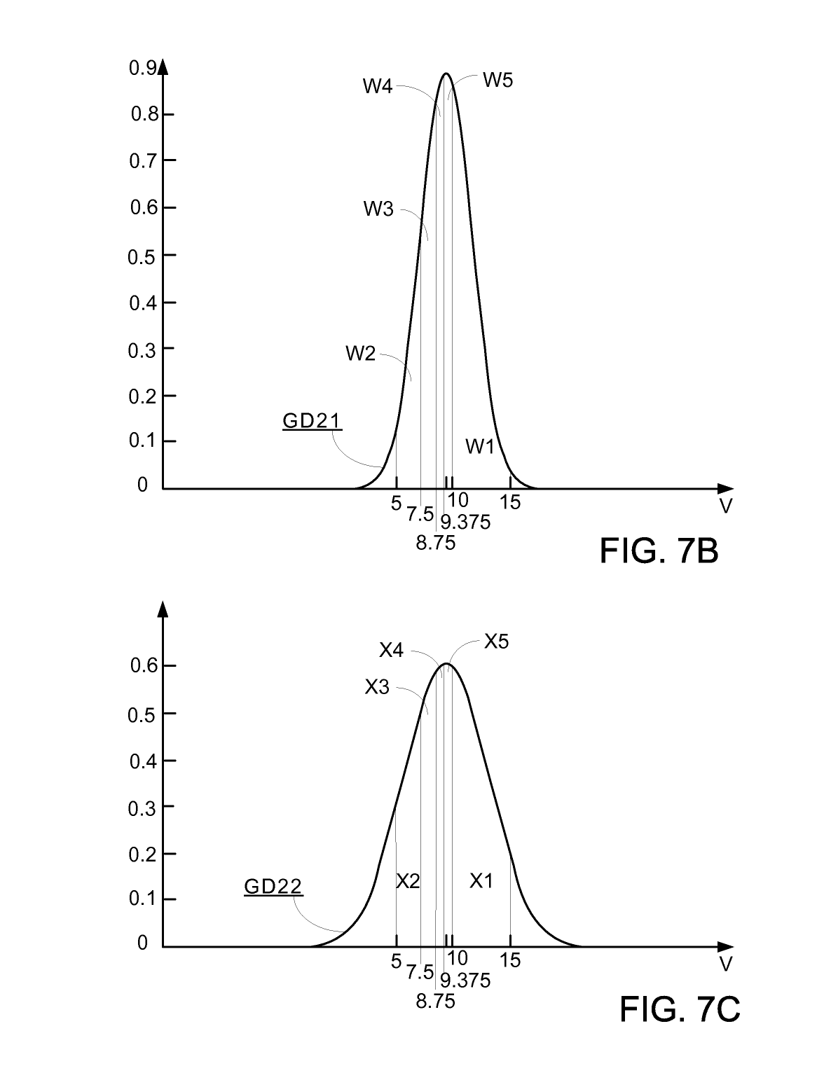

Next, plural candidate location parameters within the location parameter interval are selected, and plural candidate scale parameters are selected. As shown in FIG. 6, six candidate location parameters (μ1˜μ6) within the location parameter interval are selected, and plural candidate scale parameters (σ1˜σ6) are selected. Consequently, 24 candidate Gaussian distribution curves are created. It is noted that the number of the candidate location parameters and the number of the candidate scale parameters may be varied according to the practical requirements.

After the candidate Gaussian distribution curves are created, a first Gaussian distribution curve is selected from the candidate Gaussian distribution curves according to the known distribution curve table of FIG. 5E. The first Gaussian distribution curve is the best distribution curve that fits the known distribution curve table. Consequently, the first Gaussian distribution curve is the distribution curve of the specified storing state.

An approach of selecting the first Gaussian distribution curve from the candidate Gaussian distribution curves will be illustrated in more details as follows. For illustration, four candidate Gaussian distribution curves GD21˜GD24 defined by the candidate location parameter μ2 and four candidate scale parameters (σ1˜σ4) are taken as examples. The other candidate Gaussian distribution curves are calculated by the similar approach, and are not redundantly described herein.

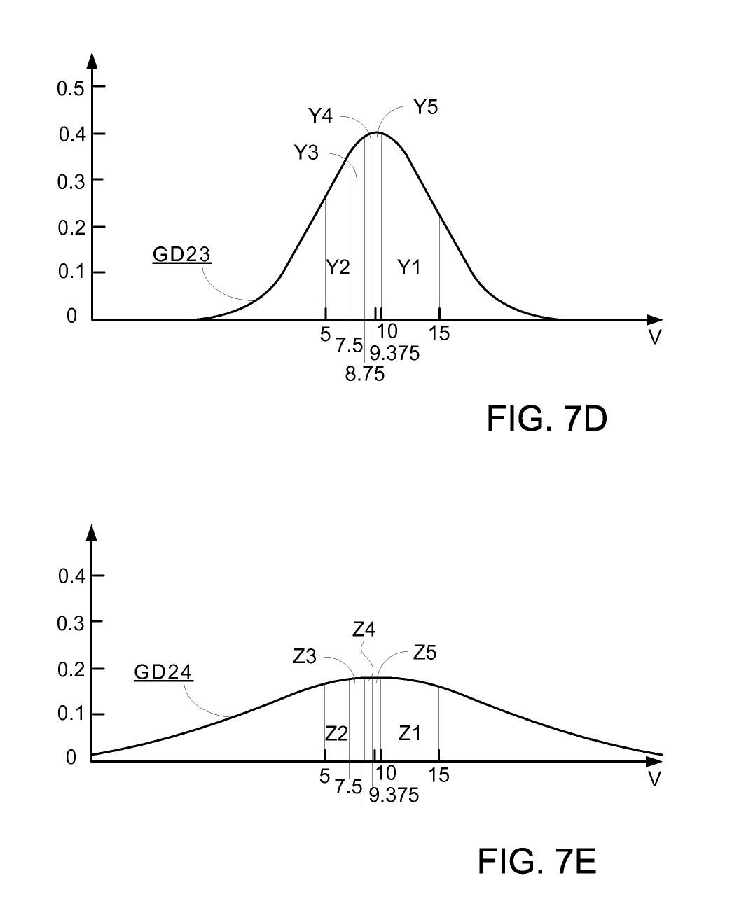

FIGS. 7A˜7E schematically illustrate the percentages of the cell number of four candidate Gaussian distribution curves GD21˜GD24 within various threshold voltage intervals.

As shown in FIG. 7A, four candidate Gaussian distribution curves GD21˜GD24 are defined by the candidate location parameter μ2 and four candidate scale parameters (σ1˜σ4). In this embodiment, the candidate location parameter μ2 is 9.5V, and the four candidate scale parameters σ1, σ2, σ3 and σ4 are 0.45, 0.70, 1.0 and 2.24, respectively.

In FIG. 7B, the candidate Gaussian distribution curve GD21 is shown. According to the above equations (1) and (2), the percentage within the threshold voltage interval between 10V and 15V is W1, the percentage within the threshold voltage interval between 5V and 7.5V is W2, the percentage within the threshold voltage interval between 7.5V and 8.75V is W3, the percentage within the threshold voltage interval between 8.75V and 9.375V is W4, and the percentage within the threshold voltage interval between 9.375V and 10V is W5.

In FIG. 7C, the candidate Gaussian distribution curve GD22 is shown. According to the above equations (1) and (2), the percentage within the threshold voltage interval between 10V and 15V is X1, the percentage within the threshold voltage interval between 5V and 7.5V is X2, the percentage within the threshold voltage interval between 7.5V and 8.75V is X3, the percentage within the threshold voltage interval between 8.75V and 9.375V is X4, and the percentage within the threshold voltage interval between 9.375V and 10V is X5.

In FIG. 7D, the candidate Gaussian distribution curve GD23 is shown. According to the above equations (1) and (2), the percentage within the threshold voltage interval between 10V and 15V is Y1, the percentage within the threshold voltage interval between 5V and 7.5V is Y2, the percentage within the threshold voltage interval between 7.5V and 8.75V is Y3, the percentage within the threshold voltage interval between 8.75V and 9.375V is Y4, and the percentage within the threshold voltage interval between 9.375V and 10V is Y5.

In FIG. 7E, the candidate Gaussian distribution curve GD24 is shown. According to the above equations (1) and (2), the percentage within the threshold voltage interval between 10V and 15V is Z1, the percentage within the threshold voltage interval between 5V and 7.5V is Z2, the percentage within the threshold voltage interval between 7.5V and 8.75V is Z3, the percentage within the threshold voltage interval between 8.75V and 9.375V is Z4, and the percentage within the threshold voltage interval between 9.375V and 10V is Z5.

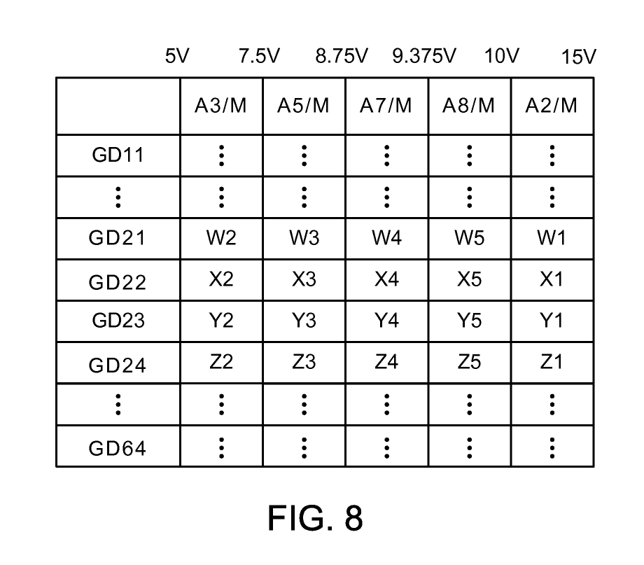

After the percentages of the cell numbers of all candidate Gaussian distribution curves GD11˜GD64 within various threshold voltage intervals are obtained, the percentages corresponding to the candidate Gaussian distribution curves and the threshold voltage intervals are listed in the table of FIG. 8.

Then, the errors between the known percentages of FIG. 5E and the calculated percentages of the candidate Gaussian distribution curves GD11˜GD64 are calculated. The candidate Gaussian distribution curve with the least error is set as the distribution curve of the specified storing state.

For example, it is assumed that the candidate Gaussian distribution curve GD22 has the least error E with respect to the known percentages of FIG. 5E. The least error E is obtained by the following formula:

$$E = \vert \frac{A 3}{M} - X 2 \vert + \vert \frac{A 5}{M} - X 3 \vert + \vert \frac{A 7}{M} - X 4 \vert + \vert \frac{A 8}{M} - X 5 \vert + \vert \frac{A 2}{M} - X 1 \vert$$

In other words, since the percentages of the candidate Gaussian distribution curve GD22 are the closest to the known percentages of FIG. 5E, the candidate Gaussian distribution curve GD22 is set as the distribution curve of the storing state A. It is noted that the way of calculating the least error is not restricted. For example, a least square method may be employed to search the least error. The operating principles of the least square method are well known to those skilled in the art, and are not redundantly described herein.

Similarly, the above approach may be used to determine the distribution curves of the other storing states (i.e. the storing states E, B and C) of the MLC solid state storage device.

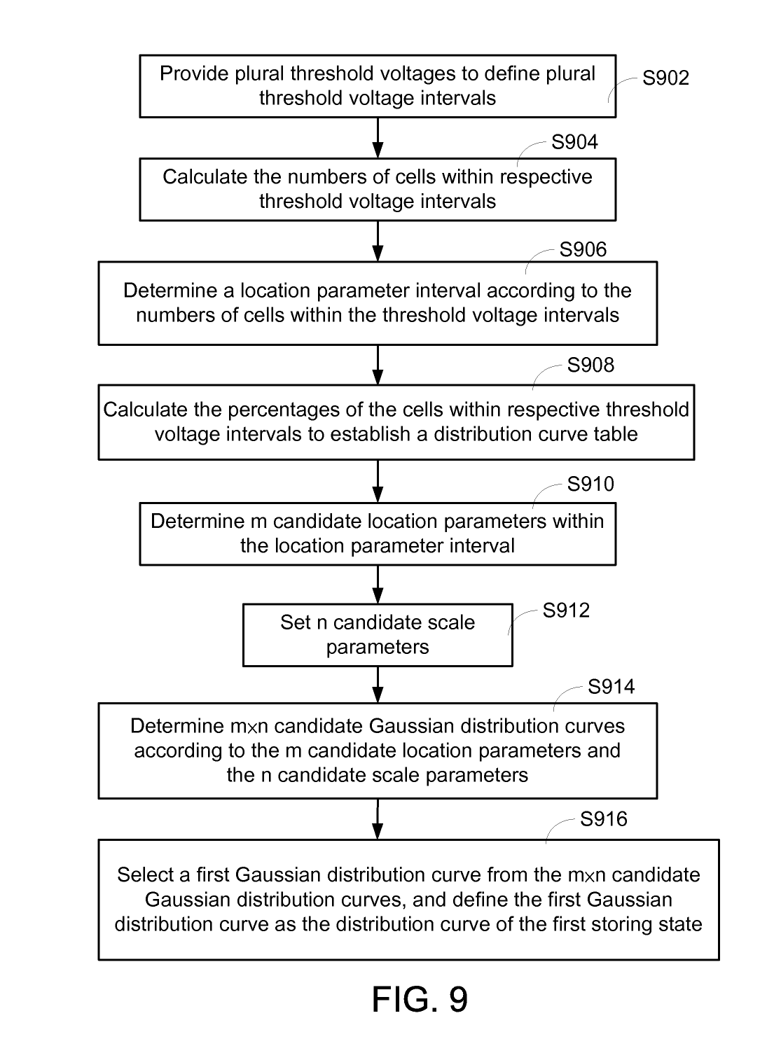

FIG. 9 is a flowchart illustrating a method for estimating a distribution curve of a storing state of a solid state storage device according to an embodiment of the present invention. The solid state storage device comprises M cells having a first storing state.

Firstly, plural threshold voltages are provided to define plural threshold voltage intervals (Step S902), and the numbers of cells within respective threshold voltage intervals are calculated (Step S904).

Then, a location parameter interval is determined according to the numbers of cells within the threshold voltage intervals (Step 906). Then, the percentages of cells within respective threshold voltage intervals and with respect to the M cells having the first storing state are calculated, and a distribution curve table is established according to the percentages and respective threshold voltage intervals (Step S908).

Then, m candidate location parameters within the location parameter interval are determined (Step S910), and n candidate scale parameters are set (Step S912). Then, m×n candidate Gaussian distribution curves are determined according to the m candidate location parameters and the n candidate scale parameters, (Step S914). Afterwards, a first Gaussian distribution curve is selected from the m×n candidate Gaussian distribution curves and defined as the distribution curve of the first storing state (Step S916). The first Gaussian distribution curve is the best distribution curve that fits the known distribution curve table.

From the above descriptions, the present invention provides a method for estimating a distribution curve of a storing state of a solid state storage device. A Gaussian distribution curve fitting the known distribution curve table is selected as the distribution curve of the specified storing state.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for estimating a distribution curve of a storing state of a solid state storage device, the solid state storage device comprising M cells with a first storing state, the distribution curve estimation method comprising steps of:
providing plural threshold voltages, thereby defining plural threshold voltage intervals;
calculating numbers of cells within respective threshold voltage intervals;
determining a location parameter interval according to the numbers of cells within the threshold voltage intervals;
calculating percentages of the cells within respective threshold voltage intervals, thereby establishing a distribution curve table;
determining m candidate location parameters within the location parameter interval;
setting n candidate scale parameters;
determining m×n candidate Gaussian distribution curves according to the m candidate location parameters and the n candidate scale parameters; and
selecting a first Gaussian distribution curve from the m×n candidate Gaussian distribution curves, and defining the first Gaussian distribution curve as the distribution curve of the first storing state.

2. The method as claimed in claim 1, wherein the step of determining the location parameter interval comprises sub-steps of:
(a) determining a first threshold voltage and a second threshold voltage;
(b) obtaining a average threshold voltage according to the first threshold voltage and the second threshold voltage;
(c) calculating a first cell number between the first threshold voltage and the average threshold voltage;
(d) calculating a second cell number between the average threshold voltage and the second threshold voltage;
(e) if the first cell number is larger than the second cell number, setting the second threshold voltage as the average threshold voltage, or if the first cell number is not larger than the second cell number, setting the first threshold voltage as the average threshold voltage; and
(f) if the number of times the step (e) is executed is smaller than a specified number, going back to the step (b), or if the number of times the step (e) is executed reaches specified number, setting a range between the first threshold voltage and the second threshold voltage as the location parameter interval.

3. The method as claimed in claim 2, wherein the step of calculating the first cell number comprises sub-steps of:
sensing the M cells by using the first threshold voltage as a sensing voltage, thereby acquiring a first sensed cell number;
sensing the M cells by using the average threshold voltage as a sensing voltage, thereby acquiring a second sensed cell number; and
subtracting the first sensed cell number from the second sensed cell number, thereby obtaining the first cell number.

4. The estimation method as claimed in claim 1, wherein a specified threshold voltage interval of the plural threshold voltage intervals is served as the location parameter interval, wherein a median threshold voltage of the first storing state lies within the location parameter interval.

5. The estimation method as claimed in claim 1, wherein after the numbers of the cells within respective threshold voltage intervals are divided by M, the percentages of the cells within respective threshold voltage intervals are obtained, and the distribution curve table is established according to the percentages.

6. The method as claimed in claim 1, wherein the step of selecting the first Gaussian distribution curve comprises sub-steps of:
calculating percentages of areas under the m×n candidate Gaussian distribution curves and within respective threshold voltage intervals; and
calculating relative errors between the percentages of the m×n candidate Gaussian distribution curves and the corresponding percentages of the distribution curve table, wherein the percentages of first Gaussian distribution curve has the least error with respect to the corresponding percentages of the distribution curve table.

7. A method for estimating a distribution curve of a storing state of a solid state storage device, the solid state storage device comprising M cells with a first storing state, the distribution curve estimation method comprising steps of:
providing plural threshold voltages, thereby defining plural threshold voltage intervals;
calculating numbers of cells within respective threshold voltage intervals;
determining a location parameter interval according to the numbers of cells within the threshold voltage intervals;
determining m×n candidate Gaussian distribution curves according to m candidate location parameters and n candidate scale parameters, wherein the m candidate location parameters are within the location parameter interval; and
selecting a first Gaussian distribution curve from the m×n candidate Gaussian distribution curves, and defining the first Gaussian distribution curve as the distribution curve of the first storing state.

8. The method as claimed in claim 7, wherein the step of determining the location parameter interval comprises sub-steps of:
(a) determining a first threshold voltage and a second threshold voltage;
(b) obtaining a average threshold voltage according to the first threshold voltage and the second threshold voltage;
(c) calculating a first cell number between the first threshold voltage and the average threshold voltage;
(d) calculating a second cell number between the average threshold voltage and the second threshold voltage;
(e) if the first cell number is larger than the second cell number, setting the second threshold voltage as the average threshold voltage, or if the first cell number is not larger than the second cell number, setting the first threshold voltage as the average threshold voltage; and
(f) if the number of times the step (e) is executed is smaller than a specified number, going back to the step (b), or if the number of times the step (e) is executed reaches specified number, setting a range between the first threshold voltage and the second threshold voltage as the location parameter interval.

9. The method as claimed in claim 8, wherein the step of calculating the first cell number comprises sub-steps of:
sensing the M cells by using the first threshold voltage as a sensing voltage, thereby acquiring a first sensed cell number;
sensing the M cells by using the average threshold voltage as a sensing voltage, thereby acquiring a second sensed cell number; and
subtracting the first sensed cell number from the second sensed cell number, thereby obtaining the first cell number.

10. The estimation method as claimed in claim 7, wherein a specified threshold voltage interval of the plural threshold voltage intervals is served as the location parameter interval, wherein a median threshold voltage of the first storing state lies within the location parameter interval.

11. The estimation method as claimed in claim 7, wherein after the numbers of the cells within respective threshold voltage intervals are divided by M, percentages of the cells within respective threshold voltage intervals are obtained, and a distribution curve table is established according to the percentages.

12. The method as claimed in claim 11, wherein the step of selecting the first Gaussian distribution curve comprises sub-steps of:
calculating percentages of areas under the m×n candidate Gaussian distribution curves and within respective threshold voltage intervals; and
calculating relative errors between the percentages of the m×n candidate Gaussian distribution curves and the corresponding percentages of the distribution curve table, wherein the percentages of first Gaussian distribution curve has the least error with respect to the corresponding percentages of the distribution curve table.
